(19) United States
(12) Patent Application Publication
(10) Pub. No.: US 2026/0188218 A1
(43) Pub. Date: Jul. 2, 2026

(54) DISPLAY APPARATUS AND DRIVING METHOD THEREOF

(71) Applicant: LG Display Co., Ltd., Seoul (KR)

(72) Inventors: Won Sang RYU, Paju-si (KR); Young Hyun KO, Paju-si (KR)

(73) Assignee: LG Display Co., Ltd., Seoul (KR)

(21) Appl. No.: 19/254,724

(22) Filed: Jun. 30, 2025

(30) Foreign Application Priority Data
Dec. 31, 2024 (KR) 10-2024-0203033

(51) Int. Cl. G09G 3/3233

(52) U.S. Cl. CPC G09G 3/3233; G09G 2300/0426; G09G 2300/0465; G09G 2300/0852; G09G 2310/08

(57) ABSTRACT

A display apparatus includes a display panel including a first subpixel and a second subpixel and a driver configured to drive the display panel, wherein the second subpixel is configured to operate based on a difference voltage between a first data voltage applied to the first subpixel and a second data voltage applied to the second subpixel.

### CROSS-REFERENCE TO RELATED APPLICATION

This application claims the benefit of Korean Patent Application No. 10-2024-0203033 filed on Dec. 31, 2024, which is hereby incorporated by reference as if fully set forth herein.

### BACKGROUND

### Field of the Disclosure

The present disclosure relates to a display apparatus and a driving method thereof.

### Discussion of the Related Art

As information technology advances, the market for display apparatuses which are connection mediums connecting a user with information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

### SUMMARY

The present disclosure provides a display apparatus in which a separate reference line for applying a reference voltage may be removed, and thus, a layout of a display area may be simplified, and layout efficiency may increase, thereby securing/enhancing an aperture ratio of a subpixel.

To achieve these objects and other advantages and in accordance with the purpose of the disclosure, as embodied and broadly described herein, a display apparatus includes: a display panel including a first subpixel and a second subpixel; and a driver configured to drive the display panel, wherein the second subpixel is configured to operate based on a difference voltage between a first data voltage applied to the first subpixel and a second data voltage applied to the second subpixel.

The display panel may include a connection line configured to electrically connect the first subpixel to the second subpixel.

The first subpixel may include a first switching transistor configured to transfer the first data voltage to a first electrode of a first capacitor, and the second subpixel may include a second switching transistor configured to transfer the second data voltage to a first electrode of a second capacitor.

The first switching transistor may include: a 1A^{th} switching transistor configured to transfer the first data voltage to a second electrode of the second capacitor; and a 1B^{th} switching transistor configured to transfer the first data voltage to the first electrode of the first capacitor.

One end of the connection line may be connected to a connection node connected to a second electrode of the 1A^{th} switching transistor and a first electrode of the 1B^{th} switching transistor, and the other end of the connection line may be connected to the second electrode of the second capacitor.

A gate electrode of the first switching transistor may be connected to a first gate line, and a gate electrode of the second switching transistor may be connected to a second gate line disposed in a line next to the first gate line.

The first subpixel may include: a 1A^{th} switching transistor including a gate electrode connected to a first gate line and a first electrode connected to a first data line; a 1B^{th} switching transistor including a gate electrode connected to the first gate line and a first electrode connected to a second electrode of the 1A^{th} switching transistor; a first capacitor including a first electrode connected to a second electrode of the 1B^{th} switching transistor; a first driving transistor including a gate electrode connected to the second electrode of the 1B^{th} switching transistor and the first electrode of the first capacitor, a first electrode connected to a high-level voltage line, and a second electrode connected to a second electrode of the first capacitor; and a light emitting diode including an anode electrode connected to the second electrode of the first capacitor and the second electrode of the first driving transistor and a cathode electrode connected to a low-level voltage line.

A connection node connected to the second electrode of the 1A^{th} switching transistor and the first electrode of the 1B^{th} switching transistor may be connected to a second electrode of a second capacitor included in the second subpixel.

In another aspect of the present disclosure, a driving method of the display apparatus, including the display panel and a driver driving the display panel, includes: applying the first data voltage to the first subpixel; applying the second data voltage to the second subpixel to form a difference voltage between the first data voltage and the second data voltage in a capacitor included in the second subpixel; driving a driving transistor included in the second subpixel to generate a driving current, based on the difference voltage stored in the capacitor included in the second subpixel; and configuring a light emitting diode included in the second subpixel to emit light, based on the driving current.

The first data voltage may be transferred to a second electrode of a capacitor included in the second subpixel through a connection line disposed between the first subpixel and the second subpixel.

When displaying full white on the display panel, at least one of the first data voltage and the second data voltage progressively increases.

When displaying another color after displaying full white on the display panel, at least one of the first data voltage and the second data voltage progressively decreases.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain the principles of the present disclosure. In the drawings:

FIG. 1 is a block diagram schematically illustrating a light emitting display apparatus according to example embodiments;

FIGS. 2 and 3 are diagrams for describing an example configuration of a gate driver of a gate in panel (GIP) type;

FIG. 4 is a diagram illustrating a configuration of a subpixel according to a first example embodiment;

FIG. 5 is a diagram for describing an operation characteristic of the subpixel according to the first example embodiment;

FIG. 6 is a diagram illustrating a configuration of a subpixel according to a second example embodiment;

FIG. 7 is a diagram for describing an operation characteristic of the subpixel according to the second example embodiment;

FIG. 8 is a diagram illustrating a configuration of a subpixel according to a third example embodiment;

FIG. 9 is a diagram for describing an operation characteristic of the subpixel according to the third example embodiment;

FIGS. 10 and 11 are diagrams for showing a transfer path of each of a first data voltage and a second data voltage with respect to the operation characteristic of FIG. 9;

FIGS. 12 and 13 are diagrams for describing an operation voltage condition difference between a driving transistor according to a comparative example and a driving transistor according to an example embodiment;

FIGS. 14 and 15 are diagrams for describing a data voltage charge characteristic difference between the comparative example and an example embodiment;

FIG. 16 is a diagram for describing a threshold voltage compensation method of a light emitting display apparatus implemented based on the first to third example embodiments;

FIG. 17 is a diagram illustrating a circuit configuration of a first switching transistor according to a fourth example embodiment; and

FIG. 18 is a diagram illustrating a layout of the first switching transistor illustrated in FIG. 17.

### DETAILED DESCRIPTION

Hereinafter, the present disclosure will be described more fully with reference to the accompanying drawings, in which example embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

A display apparatus according to the present disclosure may be applied to televisions (TVs), video players, personal computers (PCs), home theaters, electronic devices for vehicles, and smartphones, but is not limited thereto. The display apparatus according to the present disclosure may be implemented as a light emitting display apparatus, a quantum dot display (QDD) apparatus, or a liquid crystal display (LCD) apparatus. Hereinafter, for convenience of description, a light emitting display apparatus self-emitting light by using an inorganic light emitting diode or an organic light emitting diode will be described for example.

Moreover, a transistor described below may be implemented with an n-type transistor, a p-type transistor, or a combination of an n-type transistor and a p-type transistor. A transistor may be a three-electrode element including a gate, a source, and a drain. The source may be an electrode which provides a carrier to a transistor. In the transistor, a carrier may start to flow from the source. The drain may be an electrode where the carrier flows from the transistor to the outside. That is, in the transistor, the carrier flows from the source to the drain.

In the p-type transistor, because a carrier is a hole, a source voltage may be higher than a drain voltage so that the hole flows from the source to the drain. In the p-type transistor, because the hole flows from the source to the drain, a current may flow from the source to the drain. On the other hand, in the n-type transistor, because a carrier is an electron, a source voltage may be lower than a drain voltage so that the electron flows from the source to the drain. In the n-type transistor, because the electron flows from the drain to the source, a current may flow from the drain to the source. However, a source and a drain of a transistor may switch therebetween based on a voltage applied thereto. Based thereon, in the following description, one of a source and a drain will be described as a first electrode, and the other of the source and the drain will be described as a second electrode.

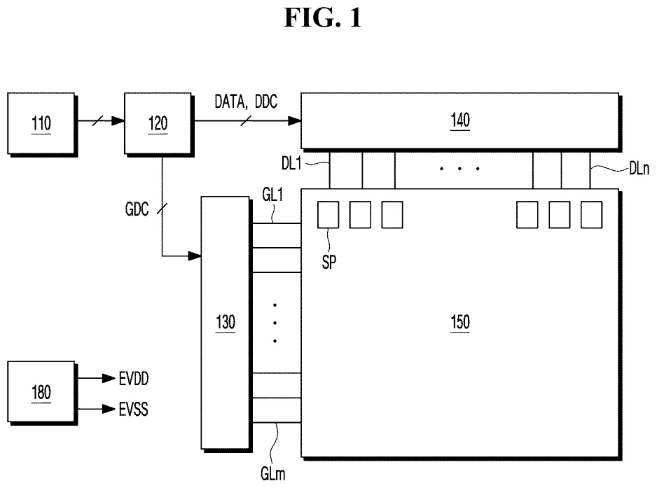

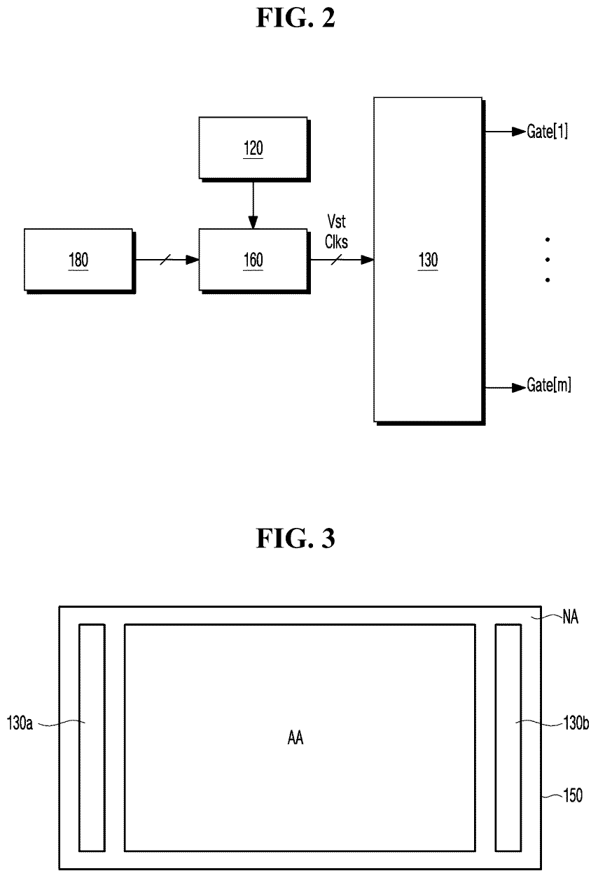

FIG. 1 is a block diagram schematically illustrating a light emitting display apparatus according to example embodiments, and FIGS. 2 and 3 are diagrams for describing an example configuration of a gate driver of a gate in panel (GIP) type.

As illustrated in FIGS. 1 to 3, a light emitting display apparatus according to an example embodiment of the present disclosure may include a timing controller (a timing control circuit) 120, a gate driver (a gate driving circuit) 130, a data driver (a data driving circuit) 140, a display panel 150, and a power supply (a power supply circuit) 180.

A video supply unit 110 (a set or a host system) may output a video data signal supplied from the outside or an image data signal stored in an internal memory thereof. The video supply unit 110 may supply a data signal and the various driving signals to the timing controller 120.

The timing controller 120 may output a gate timing control signal GDC for controlling an operation timing of the gate driver 130, a data timing control signal DDC for controlling an operation timing of the data driver 140, and various synchronization signals (a vertical synchronization signal Vsync and a horizontal synchronization signal Hsync). The timing controller 120 may provide the data driver 140 with the data timing control signal DDC and a data signal DATA supplied from the video supply unit 110. The timing controller 120 may be implemented as an integrated circuit (IC) type and may be mounted on a printed circuit board (PCB), but is not limited thereto.

In response to the gate timing control signal GDC supplied from the timing controller 120, the gate driver 120 may output a gate signal (or a gate voltage). The gate driver 130 may supply the gate signal to subpixels included in the display panel 150 through gate lines GL1 to GLm. The gate driver 130 may be formed as an IC type, or may be directly formed on the display panel 150 in a gate in panel (GIP) type, but is not limited thereto. Hereinafter, for convenience of description, as in FIGS. 2 and 3, a gate driver of a GIP type will be described for example.

The gate driver 130 may include a plurality of shift registers 130a and 130b which are provided as a GIP type at one side and the other side of a non-display area NA of the display panel 150. The shift registers 130a and 130b may be provided as a thin film type in the non-display area NA of the display panel 150, based on a GIP type. The gate driver 130 may output gate signals Gate[1] to Gate[m] for turning on or off transistors formed in a display area AA of the display panel 150.

The gate driver 130 may operate based on signals and voltages output from the timing controller 120, the power supply 180, and a level shifter 160. The level shifter 160 may generate gate control signals needed for driving of the gate driver 130, 130a, and 130b, based on the signals and the voltages output from the timing controller 120 and the power supply 180.

In response to the data timing control signal DDC supplied from the timing controller 120, the data driver 140 may sample and latch the data signal DATA, convert a digital data signal into an analog data voltage, based on a gamma reference voltage, and output the analog data voltage. The data driver 140 may respectively supply data voltages to the subpixels of the display panel 150 through a plurality of data lines DL1 to DLn. The data driver 140 may be implemented as an IC type or may be mounted on the display panel 150 or a PCB, but is not limited thereto.

The power supply 180 may generate a high-level voltage and a low-level voltage, based on an external input voltage supplied from the outside, and may output the high-level voltage and the low-level voltage through a high-level voltage line EVDD and a low-level voltage line EVSS. The power supply 180 may generate and output a voltage needed for driving of the gate driver 130 or a voltage needed for driving of the data driver 140, in addition to the high-level voltage and the low-level voltage.

The display panel 150 may be manufactured based on a substrate, having stiffness or flexibility, such as glass, silicone, or polyimide. The display panel 150 may include a plurality of subpixels SP for displaying an image. The subpixel SP may self-emit light toward an upper surface or the upper substrate and a lower substrate of the display panel 150. The subpixel SP may emit light having one color of red, green, blue, and white. The display panel 150 may display an image, based on a pixel configured with a red subpixel, a green subpixel, and a blue subpixel or a pixel configured with a red subpixel, a green subpixel, a blue subpixel, and a white subpixel.

In the above description, each of the timing controller 120, the gate driver 130, and the data driver 140 has been described as an individual element. However, based on an implementation type of the light emitting display apparatus, one or more of the timing controller 120, the gate driver 130, and the data driver 140 may be integrated into one IC.

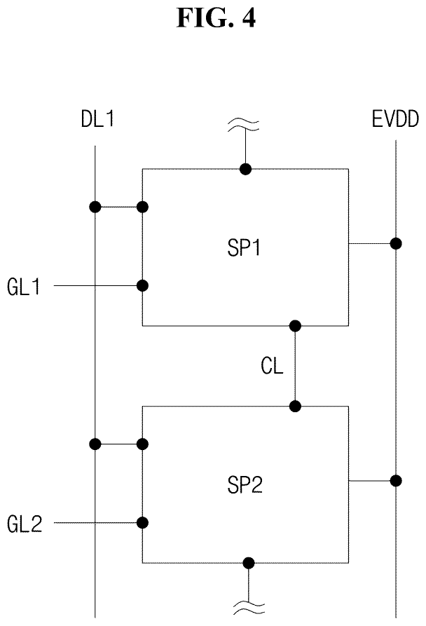

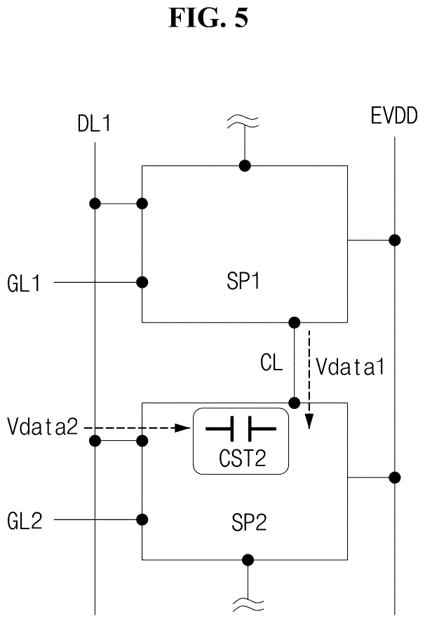

FIG. 4 is a diagram illustrating a configuration of a subpixel according to a first example embodiment, and FIG. 5 is a diagram for describing an operation characteristic of the subpixel according to the first example embodiment.

As illustrated in FIG. 4, a display panel according to the first example embodiment may include a first subpixel SP1 and a second subpixel SP2. The first subpixel SP1 and the second subpixel SP2 may be connected to a first data line DL1 and a high-level voltage line EVDD arranged in a vertical direction in common.

The first subpixel SP1 may be connected to a first gate line GL1 which is arranged in a horizontal direction and to which a first gate signal is applied, and the second subpixel SP2 may be connected to the first gate line GL1 which is arranged in the horizontal direction and to which the first gate signal is applied. To provide an additional description, the first subpixel SP1 and the second subpixel SP2 may be disposed vertically adjacent to each other, but are not limited thereto and may be disposed in different horizontal lines.

The first subpixel SP1 and the second subpixel SP2 may be disposed in different horizontal lines, and a specific node may be electrically connected thereto by a connection line CL.

As illustrated in FIG. 5, a second capacitor CST2 included in the second subpixel SP2 may be charged with a data voltage, based on a difference voltage between a first data voltage (a previous-end data voltage) Vdata1 applied to the first subpixel SP1 and a second data voltage (a current-end data voltage or its data voltage) Vdata2 applied to the second subpixel SP2.

Subsequently, the second subpixel SP2 may operate with a data voltage provided based on the difference voltage between the first data voltage Vdata1 and the second data voltage Vdata2 and may emit light.

Moreover, each of the first subpixel SP1 and the second subpixel SP2 may include an element which transfers a data voltage, an element which stores the data voltage, an element which generates a driving current, based on the data voltage, and an element which emits light, based on the driving current, and elements relevant thereto may refer to a second example embodiment described below.

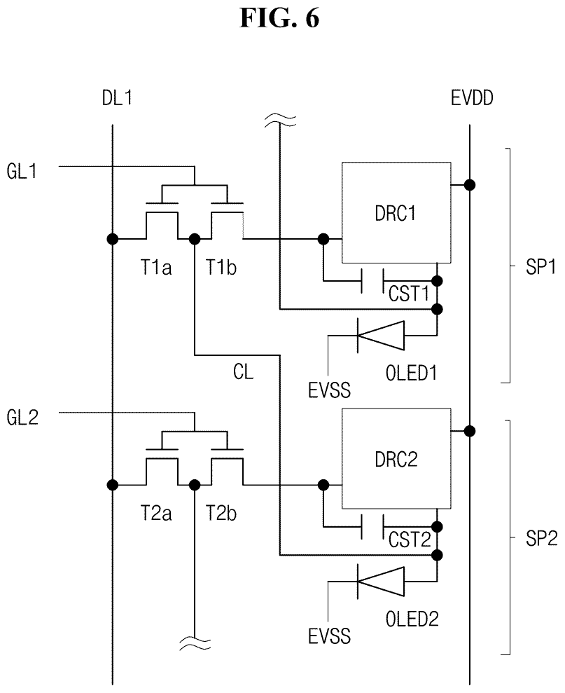

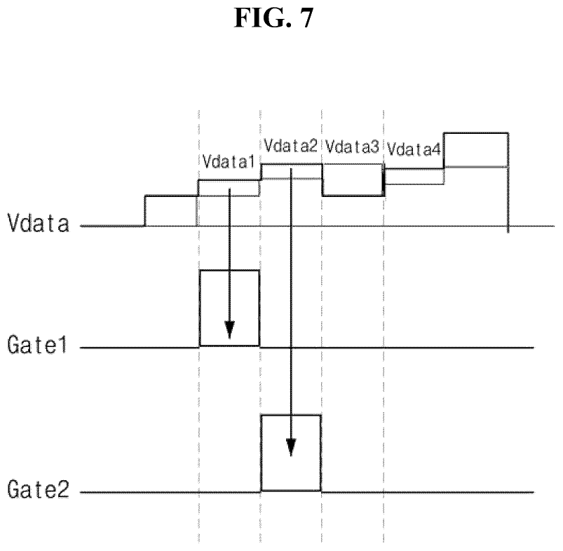

FIG. 6 is a diagram illustrating a configuration of a subpixel according to a second example embodiment, and FIG. 7 is a diagram for describing an operation characteristic of the subpixel according to the second example embodiment.

As illustrated in FIG. 6, a display panel according to the second example embodiment may include a first subpixel SP1 and a second subpixel SP2. Each of the first subpixel SP1 and the second subpixel SP2 may include switching transistors T1a, T1b, T2a, and T2b, capacitors CST1 and CST2, light emitting didoes OLED1 and OLED2, and driving circuits DRC1 and DRC2.

The first subpixel SP1 and the second subpixel SP2 may include the same elements, and thus, relevant elements will be described below with reference to the first subpixel SP1.

The first subpixel SP1 may include a 1A^{th} switching transistor T1a, a 1B^{th} switching transistor T1b, a first capacitor CST1, a first light emitting diode OLED1, and a first driving circuit DRC1. Hereinafter, the 1A^{th} switching transistor T1a and the 1B^{th} switching transistor T1b selected as an n type will be described, but are not limited thereto and may be selected as a p type.

The 1A^{th} switching transistor T1a may include a gate electrode connected to a first gate line GL1, a first electrode connected to a first data line DL1, and a second electrode connected to a first electrode of the 1B^{th} switching transistor T1b. The 1A^{th} switching transistor T1a may be turned on based on a first gate signal applied through the first gate line GL1 and may transfer a first data voltage, applied through the first data line DL1, to the first electrode of the 1B^{th} switching transistor T1b.

The 1B^{th} switching transistor T1b may include a gate electrode connected to the first gate line GL1, a first electrode connected to the second electrode of the 1A^{th} switching transistor T1a, and a second electrode connected to a first electrode of the first capacitor CST1. The 1B^{th} switching transistor T1b may be turned on based on the first gate signal applied through the first gate line GL1 and may transfer the first data voltage, applied through the 1A^{th} switching transistor T1a, to the first electrode of the first capacitor CST1.

The first driving circuit DRC1 may include a first terminal connected to a high-level voltage line EVDD, a second terminal connected to the second electrode of the 1B^{th} switching transistor T1b and the first electrode of the first capacitor CST1, and a third terminal connected to a second electrode of the first capacitor CST1. The first driving circuit DRC1 may generate the driving current, based on a voltage supplied from the first capacitor CST1. The first driving circuit DRC1 may include a driving transistor for generating the driving current or a circuit for compensating for the driving transistor.

The first capacitor CST1 may include the first electrode connected to the second electrode of the 1B^{th} switching transistor T1b and the second electrode connected to an anode electrode of the first light emitting diode OLED1 and the third terminal, which is an output node, of the first driving circuit DRC1. The first capacitor CST1 may provide a voltage needed for an operation of the first driving circuit DRC1.

The first light emitting diode OLED1 may include the anode electrode connected to the second electrode of the first capacitor CST1 and the third terminal, which is the output node, of the first driving circuit DRC1 and a cathode electrode connected to a low-level voltage line EVSS. The first light emitting diode OLED1 may operate with the driving current generated from the first driving circuit DRC1 and may emit light.

The first subpixel SP1 and the second subpixel SP2 may be disposed in different horizontal lines, and a specific node may be electrically connected thereto by a connection line CL. This will be described below.

One end (first end) of the connection line CL may be connected to a connection node connected to the second electrode of the 1A^{th} switching transistor T1a and the first electrode of the 1B^{th} switching transistor T1b included in the first subpixel SP1, and the other end (second end) of the connection line CL may be connected to the anode electrode of the second light emitting diode OLED2 and the second electrode of the second capacitor CST2 included in the second subpixel SP2.

As illustrated in FIGS. 6 and 7, a first switching transistor T1a and T1b included in the first subpixel SP1 may be turned on for a first time, based on a first gate signal Gate1 applied through the first gate line GL1. When the first switching transistor T1a and T1b is turned on, a first data voltage Vdata1 applied through the first data line DL1 may be output to different nodes by the 1A^{th} switching transistor T1a and the 1B^{th} switching transistor T1b.

Second switching transistors T2a and T2b included in the second subpixel SP2 may be turned on for a second time succeeding the first time, based on a second gate signal Gate2 applied through the second gate line GL2. When the second switching transistors T2a and T2b are turned on, a second data voltage Vdata2 applied through the first data line DL1 may be output to different nodes by the 2A^{th} switching transistor T2a and the 2B^{th} switching transistor T2b.

Furthermore, in FIG. 7, to show that a data voltage may vary at every one horizontal time, for example, it is illustrated that the second data voltage Vdata2 is output to be higher than the first data voltage Vdata1, a third data voltage Vdata3 is output to be lower than the second data voltage Vdata2, and a fourth data voltage Vdata4 is output to be higher than the third data voltage Vdata3.

Elements relevant to the first driving circuit DRC1 included in the first subpixel SP1 and the second driving circuit DRC2 included in the second subpixel SP2 and an operation characteristic of each of the first subpixel SP1 and the second subpixel SP2 may refer to a third example embodiment described below.

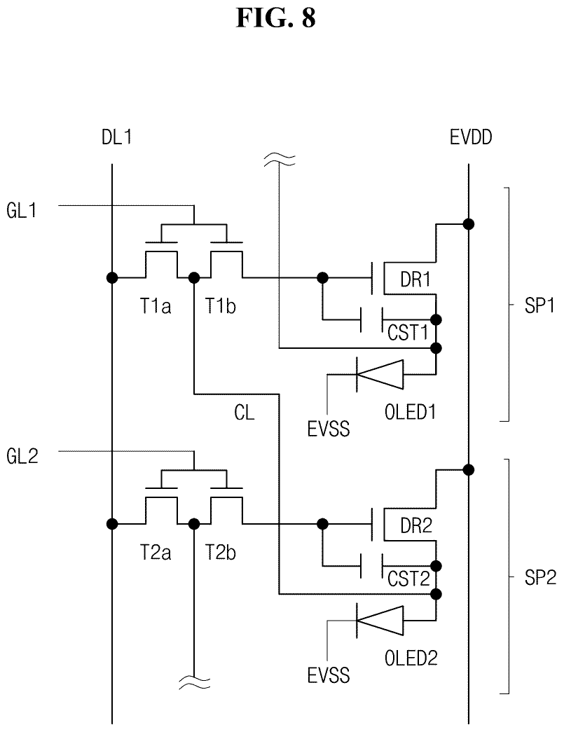

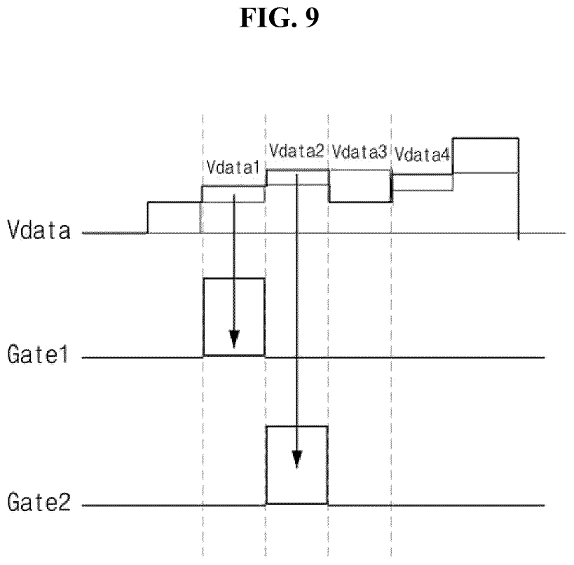

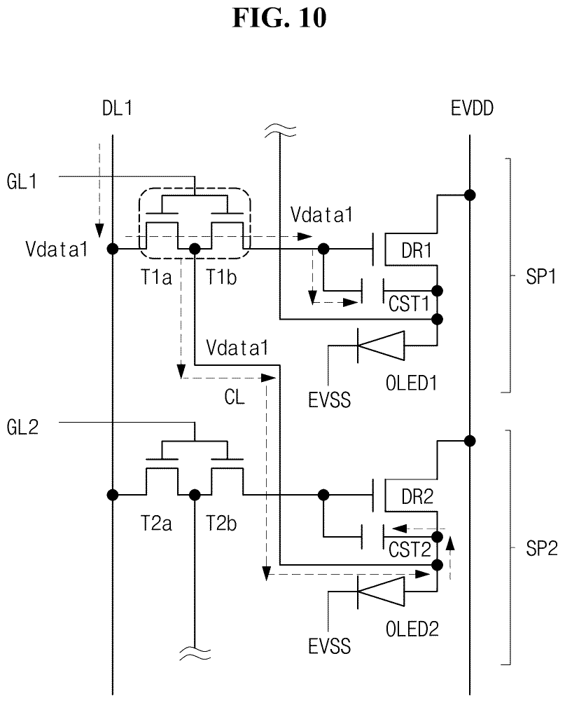

FIG. 8 is a diagram illustrating a configuration of a subpixel according to a third example embodiment, FIG. 9 is a diagram for describing an operation characteristic of the subpixel according to the third example embodiment, and FIGS. 10 and 11 are diagrams for showing a transfer path of each of a first data voltage and a second data voltage with respect to the operation characteristic of FIG. 9.

As illustrated in FIG. 8, a display panel according to the third example embodiment may include a first subpixel SP1 and a second subpixel SP2. Each of the first subpixel SP1 and the second subpixel SP2 may include switching transistors T1a, T1b, T2a, and T2b, capacitors CST1 and CST2, light emitting didoes OLED1 and OLED2, and driving circuits DRC1 and DRC2.

A first driving circuit DRC1 included in the first subpixel SP1 and a second driving circuit DRC2 included in the second subpixel SP2 may include the same elements, and thus, relevant elements will be described below with reference to the first subpixel SP1.

The first driving circuit DRC1 included in the first subpixel SP1 may include a first driving transistor DR1. The first driving transistor DR1 may include a gate electrode connected to a second electrode of a first 1B^{th} switching transistor T1b and a first electrode of a first capacitor CST1, a first electrode connected to a high-level voltage line EVDD, and a second electrode connected to a second electrode of the first capacitor CST1 and an anode electrode of a first light emitting diode OLED1.

The first driving transistor DR1 may operate based on a voltage charged in the first capacitor CST1, and this will be described below with reference to FIGS. 9 to 11. Hereinafter, the first driving transistor DR1 selected as an n type will be described, but is not limited thereto and may be selected as a p type.

As illustrated in FIGS. 9 and 10, a first switching transistor T1a and T1b included in the first subpixel SP1 may be turned on for a first time (for example, a first horizontal time), based on a first gate signal Gate1 applied through the first gate line GL1.

When the first switching transistor T1a and T1b is turned on, a first data voltage Vdata1 output through the 1B^{th} switching transistor T1b may be applied to a first electrode of the first capacitor CST1. On the other hand, the first data voltage Vdata1 output through the 1A^{th} switching transistor T1a may be transferred to, through a connection line CL, a second electrode of the second capacitor CST2 included in the second subpixel SP2.

As illustrated in FIGS. 9 and 11, second switching transistors T2a and T2b included in the second subpixel SP2 may be turned on for a second time (for example, a second horizontal time), based on a second gate signal Gate2 applied through the second gate line GL2.

When the second switching transistors T2a and T2b are turned on, a second data voltage Vdata2 output through a second electrode of the 2B^{th} switching transistor T2b may be applied to a first electrode of the second capacitor CST2. On the other hand, the second data voltage Vdata2 output through a second electrode of the 2A^{th} switching transistor T2a may be transferred to a second electrode of a third capacitor, included in a third subpixel, through a connection line disposed between the second subpixel SP2 and the third subpixel.

As the first subpixel SP1 and the second subpixel SP2 operate as described above, the second capacitor CST2 included in the second subpixel SP2 may be charged with a data voltage, based on a difference voltage between a first data voltage Vdata1 applied to the first subpixel SP1 and a second data voltage Vdata2 applied to the second subpixel SP2.

Moreover, a light emitting display apparatus including a subpixel according to an example embodiment may have an operation voltage condition of a driving transistor which differs from that of a light emitting display apparatus including a subpixel according to a comparative example and will be described below with reference to a second driving transistor in association with the preceding description.

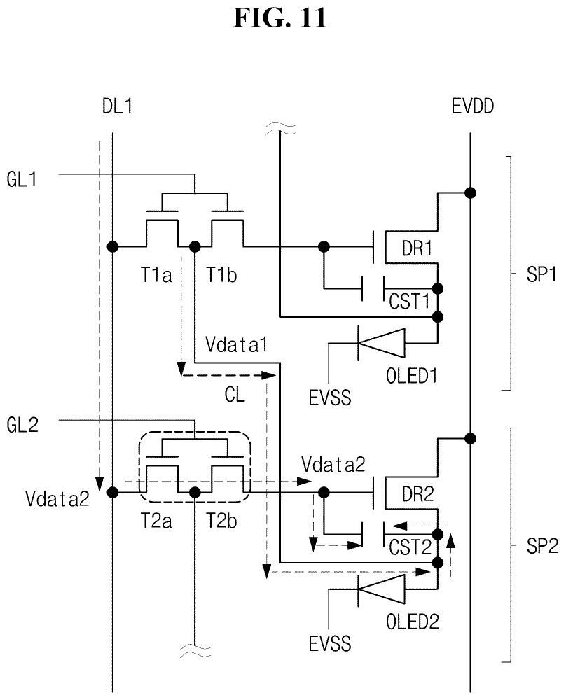

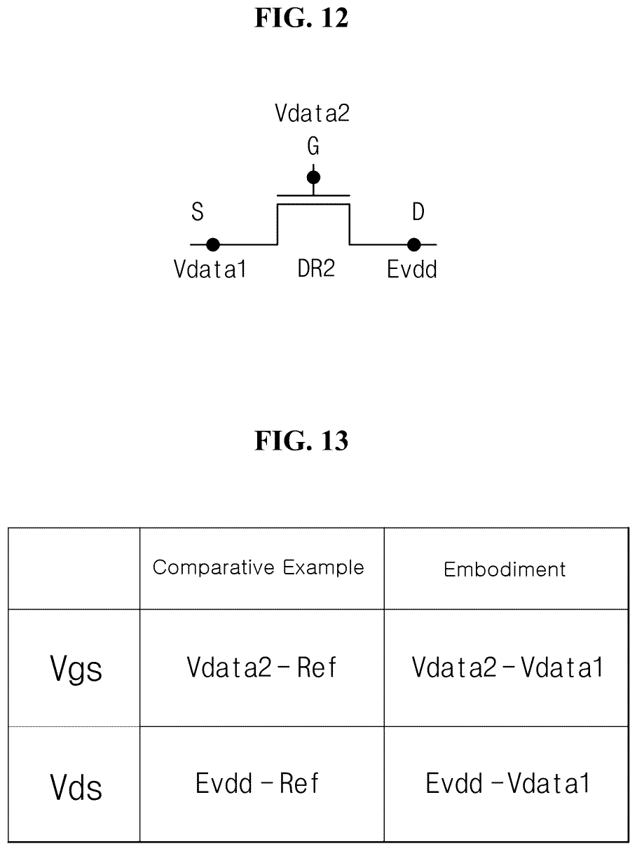

FIGS. 12 and 13 are diagrams for describing an operation voltage condition difference between a driving transistor according to a comparative example and a driving transistor according to an example embodiment, and FIGS. 14 and 15 are diagrams for describing a data voltage charge characteristic difference between the comparative example and an example embodiment.

As illustrated in FIGS. 8 and 12, the second driving transistor DR2 may include a gate electrode G, a source electrode S, and a drain electrode D. The second driving transistor DR2 may receive a second data voltage Vdata2 through the gate electrode G, may receive a first data voltage Vdata1 through the source electrode S, and may receive a high-level voltage Evdd through the drain electrode D.

As illustrated in FIGS. 12 and 13, in the second driving transistor DR2 according to an example embodiment, a gate-source voltage Vgs may be determined by a difference voltage “Vdata2-Vdata1” between the second data voltage Vdata2 and the first data voltage Vdata1, and a drain-source voltage Vds may be determined by a difference voltage “Evdd-Vdata1” between the high-level voltage Evdd and the first data voltage Vdata1.

On the other hand, in the second driving transistor DR2 according to the comparative example, a gate-source voltage Vgs may be determined by a difference voltage “Vdata2-Ref” between the first data voltage Vdata1 and a reference voltage Ref, and a drain-source voltage Vds may be determined by a difference voltage “Evdd-Ref” between the high-level voltage Evdd and the reference voltage Ref.

For reference, in the comparative example, a subpixel may further include a compensation transistor or a reference line for applying the reference voltage Ref to the source electrode S of the second driving transistor DR2.

As illustrated in FIG. 14, in the comparative example described above, when displaying full white on the display panel, the reference voltage Ref may be fixed, and the same data voltage Vdata may be applied to pixels 1st PXL to 4th PXL of one data line. Accordingly, in the comparative example, in order to display full white on the display panel, the same data voltage Vdata may be applied to the pixels 1st PXL to 4th PXL of one data line.

On the other hand, in an example embodiment, when displaying full white on the display panel, the first data voltage Vdata1 used as the reference voltage Ref and the second data voltage Vdata2 may be applied to progressively increase for each of the pixels 1st PXL to 4th PXL of one data line. Accordingly, in an example embodiment, to display full white on the display panel, a data voltage which progressively increases may be applied for each of the pixels 1st PXL to 4th PXL of one data line.

Furthermore, in an example embodiment, when displaying another color after displaying full white on the display panel, the first data voltage Vdata1 used as the reference voltage Ref and the second data voltage Vdata2 may progressively decrease for each of the pixels 1st PXL to 4th PXL of one data line.

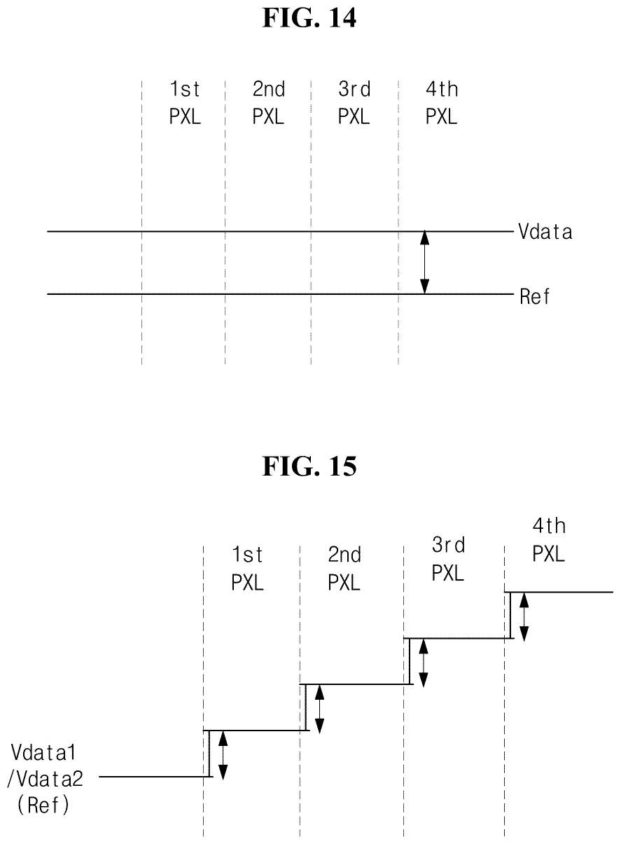

FIG. 16 is a diagram for describing a threshold voltage compensation method of a light emitting display apparatus implemented based on the first to third example embodiments.

As illustrated in FIG. 16, a light emitting display apparatus implemented based on the first to third example embodiments may include a data driver 140 which includes a voltage output circuit 141 which outputs a data voltage, which is to be applied to a subpixel SP, through a first data line DL1, a pixel sensing circuit 145 which senses an element included in the subpixel SP through the first data line DL1, and a selection switch SW.

The data driver 140 may control the selection switch SW so that the first data line DL1 is electrically connected to the voltage output circuit 141 during a normal display driving period, and then, may output a data voltage for driving the subpixel SP.

The data driver 140 may control the selection switch SW so that the first data line DL1 is electrically connected to the pixel sensing circuit 145 during a separately defined sensing driving period, and then, may sense the element included in the subpixel SP to obtain a sensing value.

The data driver 140 may transfer a sensed sensing voltage to the timing controller 120 during the sensing driving period in connection with the timing controller 120. The timing controller 120 may compensate for and output a data signal, based on the sensing value transferred from the data driver 140. To this end, the timing controller 120 may further include a degradation determiner 128 and a degradation compensator 129.

The degradation determiner 128 may determine whether a driving transistor or a light emitting diode is degraded, based on the sensing value, and when a degradation occurs, the degradation determiner 128 may output a degradation value. The degradation compensator 129 may calculate a compensation value, based on the degradation value output from the degradation determiner, and may reflect the compensation value in a data signal which is to be supplied to the data driver 140.

The timing controller 120 may determine a degradation in a threshold voltage of a driving transistor or a threshold voltage of a light emitting diode and may compensate for the degradation, based on a method (i.e., a sensing-less method) which counts an input data signal to analyze a gray level or analyze the amount of use of the data signal. In this case, the data driver 140 may not include a circuit such as the pixel sensing circuit 145 and the selection switch SW without the separate sensing driving period.

Furthermore, in the present disclosure, an example where transistors included in a subpixel are implemented as an n type is illustrated. However, this may be merely one example embodiment, the transistors included in the subpixel may be implemented as a p type, or may be implemented as a type where an n type and a p type are combined.

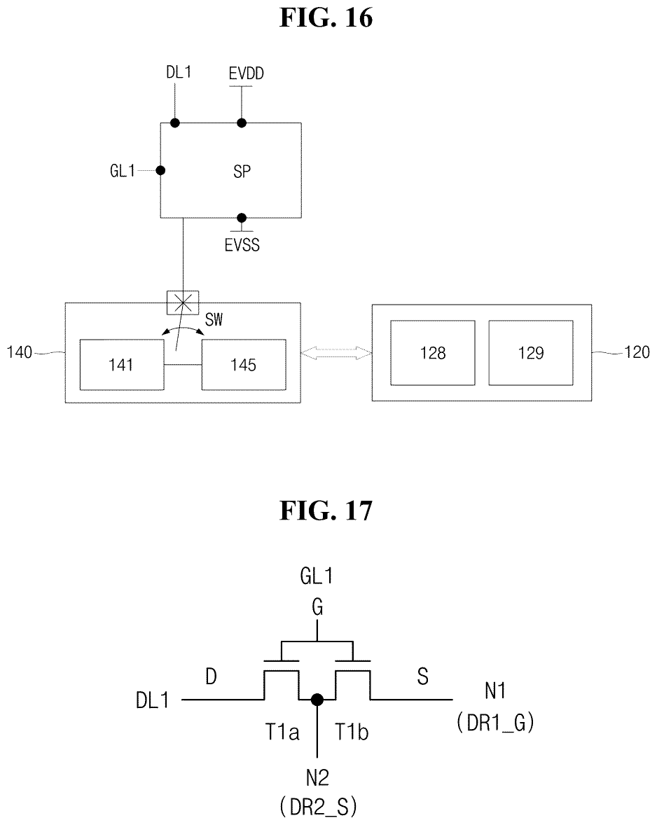

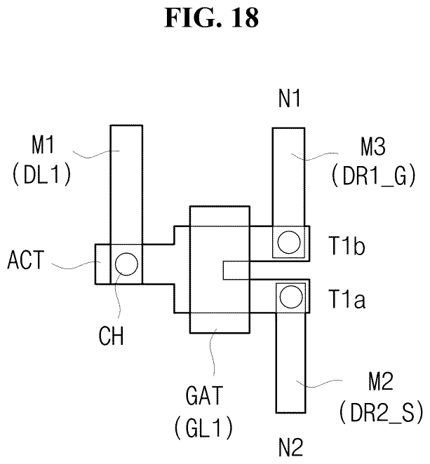

FIG. 17 is a diagram illustrating a circuit configuration of a first switching transistor according to a fourth example embodiment, and FIG. 18 is a diagram illustrating a layout of the first switching transistor illustrated in FIG. 17.

As illustrated in FIG. 17, a second electrode of a 1A^{th} switching transistor T1a included in a first switching transistor T1a and T1b may be connected to a second node N2, and a second electrode of a 1B^{th} switching transistor T1b may be connected to a first node N1.

The first switching transistor T1a and T1b may respectively transfer a data voltage, applied through a first data line DL1, to the first node N1 and the second node N2. As described above in the second example embodiment and the third example embodiment, the first node N1 may be connected to a gate electrode DR1_G of a first driving transistor included in a first subpixel, and the second node N2 may be connected to a second electrode DR2_S of a second driving transistor included in a second subpixel.

The first switching transistor T1a and T1b may transfer the same data voltages to different nodes, and thus, may be configured as follows, so that the first node N1 and the second node N2 are independent of each other so as to prevent or suppress the data voltage from being mixed after the data voltages are transferred.

As illustrated in FIGS. 17 and 18, the first switching transistor T1a and T1b may configure a 1A^{th} switching transistor T1a and a 1B^{th} switching transistor T1b, based on a first metal layer M1, a second metal layer M2, a third metal layer M3, an active layer ACT, and a gate metal layer GAT.

The active layer ACT and the gate metal layer GAT may overlap to be shared by the 1A^{th} switching transistor T1a and the 1B^{th} switching transistor T1b. The active layer ACT may be patterned in a fork shape where a portion connected to the first metal layer M1 has one branch (a first branch), and a portion connected to the second metal layer M2 and the third metal layer M3 has two branches (second and third branches). In the active layer ACT, with respect to a region overlapping the gate metal layer GAT, the first branch may be disposed at a first side (a left side), and the second and third branches may be disposed apart from each other at a second side (a right side).

The gate metal layer GAT may be a portion connected to the first gate line GL1 and may be a gate electrode G of the first switching transistor T1a and T1b. The gate metal layer GAT may be divided by an insulation layer and may be disposed on a layer which differs from the metal layers M1 to M3 and the active layer ACT.

The first metal layer M1 may be a portion connected to the first data line DL1 and may be a drain electrode D of the first switching transistor T1a and T1b. The first metal layer M1 may be electrically connected to the first branch of the active layer ACT through a contact hole CH. The first metal layer M1 may be disposed in a vertical direction.

The second metal layer M2 may be a portion connected to the second node N2 and may be a contact point between a 1A^{th} switching transistor T1a and a 1B^{th} switching transistor T1b. The second metal layer M2 may be electrically connected to the second branch of the active layer ACT through the contact hole CH. The second metal layer M2 and the third metal layer M3 may be disposed in the vertical direction and may be spaced apart from each other to be electrically disconnected with each other.

The third metal layer M3 may be a portion connected to the first node N1 and may be source electrode S of the first switching transistor T1a and T1b. The third metal layer M3 may be electrically connected to the third branch of the active layer ACT through the contact hole CH. The third metal layer M3 and the first metal layer M1 may be disposed in a horizontal direction and may be spaced apart from each other to be electrically disconnected with each other.

As seen in the structure, the first node N1 and the second node N2 may be physically connected to each other by the active layer ACT, but when the active layer ACT is deactivated (i.e., turned off), the first node N1 and the second node N2 may maintain an electrically disconnected state.

Therefore, the first switching transistor T1a and T1b may have a structure where data voltages are transferred to different nodes and then are not mixed. Also, the first switching transistor T1a and T1b may be implemented to occupy a narrow area, based on having the structure.

Furthermore, in FIG. 18, it is illustrated that the metal layers M1 to M3 and the gate metal layer GAT are disposed in a vertical direction, the active layer ACT is disposed in a horizontal direction, and the layers have a rectilinear shape. However, this may be merely for helping understand the first switching transistor T1a and T1b, and an arrangement structure and a shape of the first switching transistor T1a and T1b are not limited thereto.

Hereinabove, the present disclosure may use a previous-end data voltage as a reference voltage and may form a gate-source voltage of a driving transistor by using a difference voltage between the previous-end data voltage and a current-end data voltage, and based thereon, may drive a subpixel to remove a separate reference line for applying a reference voltage. Also, because the separate reference line is removed, the present disclosure may simplify a layout of a display area may increase layout efficiency, thereby securing/enhancing an aperture ratio of a subpixel.

The effects according to the present disclosure are not limited to the above examples, and other various effects may be included in the specification.

While the present disclosure has been particularly shown and described with reference to example embodiments thereof, it should be understood by those of ordinary skill in the art that various changes in form and details may be made therein without departing from the spirit and scope of the present disclosure as may be defined, for example, by the following claims and their equivalents.

What is claimed is:

1. A display apparatus, comprising:
a display panel including a first subpixel and a second subpixel; and
a driver configured to drive the display panel,
wherein the second subpixel is configured to operate based on a difference voltage between a first data voltage applied to the first subpixel and a second data voltage applied to the second subpixel.

2. The display apparatus of claim 1, wherein the display panel comprises a connection line configured to electrically connect the first subpixel to the second subpixel.

3. The display apparatus of claim 2, wherein the first subpixel comprises a first switching transistor configured to transfer the first data voltage to a first electrode of a first capacitor, and
wherein the second subpixel comprises a second switching transistor configured to transfer the second data voltage to a first electrode of a second capacitor.

4. The display apparatus of claim 3, wherein the first switching transistor comprises:
a 1A^{th} switching transistor configured to transfer the first data voltage to a second electrode of the second capacitor; and
a 1B^{th} switching transistor configured to transfer the first data voltage to the first electrode of the first capacitor.

5. The display apparatus of claim 4, wherein one end of the connection line is connected to a connection node connected to a second electrode of the 1A^{th} switching transistor and a first electrode of the 1B^{th} switching transistor, and the other end of the connection line is connected to the second electrode of the second capacitor.

6. The display apparatus of claim 3, wherein a gate electrode of the first switching transistor is connected to a first gate line, and
wherein a gate electrode of the second switching transistor is connected to a second gate line disposed in a line next to the first gate line.

7. The display apparatus of claim 1, wherein the first subpixel comprises:
a 1A^{th} switching transistor including a gate electrode connected to a first gate line and a first electrode connected to a first data line;
a 1B^{th} switching transistor including a gate electrode connected to the first gate line and a first electrode connected to a second electrode of the 1A^{th} switching transistor;
a first capacitor including a first electrode connected to a second electrode of the 1B^{th} switching transistor;
a first driving transistor including a gate electrode connected to the second electrode of the 1B^{th} switching transistor and the first electrode of the first capacitor, a first electrode connected to a high-level voltage line, and a second electrode connected to a second electrode of the first capacitor; and
a light emitting diode including an anode electrode connected to the second electrode of the first capacitor and the second electrode of the first driving transistor and a cathode electrode connected to a low-level voltage line.

8. The display apparatus of claim 7, wherein a connection node connected to the second electrode of the 1A^{th} switching transistor and the first electrode of the 1B^{th} switching transistor is connected to a second electrode of a second capacitor included in the second subpixel.

9. A driving method of the display apparatus of claim 1, the driving method comprising:
applying the first data voltage to the first subpixel;
applying the second data voltage to the second subpixel to form a difference voltage between the first data voltage and the second data voltage in a capacitor included in the second subpixel;
driving a driving transistor included in the second subpixel to generate a driving current, based on the difference voltage stored in the capacitor included in the second subpixel; and
configuring a light emitting diode included in the second subpixel to emit light, based on the driving current.

10. The driving method of claim 9, wherein the first data voltage is transferred to a second electrode of a capacitor included in the second subpixel through a connection line disposed between the first subpixel and the second subpixel.

11. The driving method of claim 9, when displaying full white on the display panel, at least one of the first data voltage and the second data voltage progressively increases.

12. The driving method of claim 11, when displaying another color after displaying full white on the display panel, at least one of the first data voltage and the second data voltage progressively decreases.
